(19) United States
(12) Patent Application Publication
(10) Pub. No.: US 2004/0264534 A1
(43) Pub. Date: Dec. 30, 2004

(54) Semiconductor laser device and method for manufacturing the same

(76) Inventor: Sang Bok Yun, Suwon (KR)

Correspondence Address: LOWE HAUPTMAN GILMAN & BERNER, LLP, Suite 310, 1700 Diagonal Road, Alexandria, VA, 22314, US

(21) Appl. No.: 10/811,807

(22) Filed: Mar. 30, 2004

(30) Foreign Application Priority Data
Jun. 26, 2003 (KR) 2003-41838

(51) Int. Cl. H01S 5/00

(52) U.S. Cl. 372/46; 372/45

(57) ABSTRACT

Disclosed is a semiconductor laser device in which a ridge is formed to have a buried structure inside cleaved surfaces in order to prevent grains from being formed at the cleaved surfaces. A method for manufacturing the semiconductor laser device is also disclosed. The semiconductor laser device comprises a first-conductivity type substrate, a first-conductivity type clad layer formed over the substrate, an active layer formed over the first-conductivity type clad layer, a second-conductivity type clad layer formed over the active layer while having a ridge spaced apart, at respective opposite longitudinal ends thereof, from a laser emitting end surface and an end surface opposite to the laser emitting end surface by a predetermined gap and a current blocking layer formed on the second-conductivity type clad layer around the ridge. In accordance with the invention, it is possible to prevent formation of grains at the cleaved surfaces.

### BACKGROUND OF THE INVENTION

1. Field of the Invention

The present invention relates to a method for manufacturing a semiconductor laser device, and more particularly to a semiconductor laser device in which a ridge is formed to have a buried structure inside cleaved surfaces in order to prevent grains from being formed at the cleaved surfaces, and a method for manufacturing the semiconductor laser device.

2. Description of the Prior Art

Generally, semiconductor laser devices have a very small volume while involving a low manufacturing cost, so that mass production thereof can be achieved. Also, such semiconductor laser devices can oscillate lasers of high power with drive current of several mA. By virtue of such features, the semiconductor laser devices have been used for light sources of optical pickup devices in optical disc systems such as CD, CD-RW, DVD, and DVD-RW. Also, they have been widely applied to diverse technical fields such as optical communication, multi-communication, and space communication. In particular, semiconductor laser devices having high optical power are required in technical fields relating to optical pickup devices, in order to achieve an increase in writing speed. An improvement in the reliability of such semiconductor laser devices is also required to obtain an improvement in product quality, and an increase in product life.

FIG. 1a is a perspective view illustrating a conventional semiconductor laser device. FIG. 1b is a plan view illustrating the structure of the conventional semiconductor laser device in a state in which a ridge has been formed. FIG. 2 is a plan view illustrating a wafer-level state of the conventional semiconductor laser device. Now, a method for manufacturing the conventional semiconductor laser device will be described with reference to FIGS. 1a, 1b, and 2. The following description will be given in conjunction with an AlGaAs-based semiconductor laser device adapted to emit a laser having a wavelength of 780 nm.

As shown in FIG. 1a, over a GaAs substrate 11 of a first conductivity type, for example, an n type, an n type AlGaAs clad layer 12 is first formed. An AlGaAs-based active layer 13 is formed over the n type AlGaAs clad layer 12. The AlGaAs-based active layer 13 has a composition different from that of the n type AlGaAs clad layer 12 while having a multi-quantum well structure. Thereafter, an AlGaAs clad layer 14 of a second conductivity type, that is, a p type, is formed over the n type AlGaAs-based active layer 13. The p type AlGaAs clad layer 14 has the same composition as that of the n type AlGaAs clad layer 12. A mask is formed on the p type AlGaAs clad layer 14 at a region where a ridge 14a is to be formed. The region where the mask is arranged corresponds to the region where the ridge 14a is to be formed. Accordingly, the p type AlGaAs clad layer 14 will not be etched at its portion corresponding to the mask region when it is subsequently subjected to an etch process, so that the ridge 14a will be formed. Thereafter, the ridge 14a is formed by etching the portion of the p type AlGaAs clad layer 14 other than the portion corresponding to the mask region. A current blocking layer 15 is then formed around the ridge 14a. The formation of the current blocking layer 15 is achieved by selectively growing an n type GaAs layer on the p type AlGaAs clad layer 14 around the ridge 14a such that it has a thickness corresponding to the height of the ridge 14a. Subsequently, a p type GaAs ohmic contact layer 16 is formed to cover the surfaces of the ridge 14a and current blocking layer 15. A certain alloy is deposited over both the upper surface of the ohmic contact layer 16 and the lower surface of the n type GaAs substrate, thereby forming electrodes 18 and 17, respectively. Referring to FIG. 1b, it can be seen that the above mentioned conventional semiconductor laser device has a structure in which the opposite lateral ends of the ridge 14a are exposed to regions A where the opposite end surfaces of the semiconductor laser device are arranged, respectively.

In such a structure in which the opposite lateral ends of the ridge 14a are exposed to respective regions A where the opposite end surfaces of the semiconductor laser device are arranged, there may be a problem in that grains are formed at cleaved facets produced when semiconductor laser devices of a wafer level are cleaved into individual semiconductor laser devices of a chip level.

FIG. 2 is a plan view illustrating a wafer-level state of the conventional semiconductor laser device. As shown in FIG. 2, semiconductor laser devices formed on a wafer in the above mentioned manner are cleaved in a direction perpendicular to a ridge extension direction in accordance with a bar making process, and then cleaved in a direction parallel to the ridge extension direction in accordance with a chip making process, so that they are singulated.

In the bar making process, the wafer is cleaved into bars along bar making lines 22 extending in a direction perpendicular to the ridge extension direction, as shown in FIG. 2. In the chip making process, each bar is cleaved into chips along chip making lines 23 extending in a direction parallel to the ridge extension direction, as shown in FIG. 2.

In accordance with the above mentioned conventional semiconductor laser device manufacturing method, masks are formed on the wafer to form respective ridges 21 of semiconductor laser devices to be formed. In FIG. 2, the masks are designated by the same reference numeral as the ridges, that is, “21”, because the ridges 21 will be formed at regions where the masks are formed, respectively. The masks are formed such that they are connected in an extension direction of the ridges 21 to be formed. Accordingly, the ridges 21 of the semiconductor laser devices are formed such that they are connected in the extension direction thereof. The semiconductor laser devices fabricated in the above mentioned manner, to have a wafer level structure, are subsequently subjected to a bar making process, so that they are singulated. However, the laminated structure of each semiconductor laser device, in particular, the ridge of the semiconductor laser device, is exposed to the opposite lateral end surfaces of the semiconductor laser device, that is, cleaved surfaces. That is, when the semiconductor laser devices are cleaved along the bar making lines 22 in the bar making process, the ridge 21 of each semiconductor laser device is also cleaved, so that its opposite lateral ends are exposed to the associated cleaved surfaces, respectively.

Since each semiconductor laser device has a laminated structure of multiple layers, it has a plurality of interfaces each defined between adjacent ones of the multiple layers. At such an interface, however, there may be physical defects because the associated laminated layers have different compositions. In a cleaving process in which cleaved surfaces are formed, such physical defects may cause grains to be formed at the cleaved surfaces when a lateral force is applied to the cleaved surfaces. In particular, the force applied to each ridge in the cleaving process is exerted on the lateral end surfaces in a direction substantially perpendicular to the lateral end surfaces, as compared to that applied to other interfaces. For this reason, the exertion direction of the force may vary, so that there is an increase in the possibility that grains are formed at the lateral end surfaces of each ridge. Such grains cause a degradation in the appearance quality of the resultant semiconductor laser device, thereby adversely affecting the characteristics of laser emitted from the semiconductor laser device.

FIGS. 3a to 3c show diverse grains formed at the cleaved surface of the conventional semiconductor laser device. As shown in FIG. 3a, formation of a grain 32 may begin in the vicinity of the ridge 31, and proceed to the interface between the substrate and the n type clad layer. In a severe case, the grain 32 formed in the vicinity of the ridge 31 may extend to a part of the substrate, as shown in FIG. 3b. In a more severe case, the grain 32 may extend over the whole portion of the substrate, as shown in FIG. 3c. Although diverse grains 32 may be formed at the cleaved surfaces of the semiconductor laser device, all of them extend from a region in the vicinity of the ridge, proceed to a region beneath the ridge, and extend into the substrate. As a result, such a grain, which causes a degradation in the appearance of the semiconductor laser device, extends through the active layer where the laser oscillates. In this case, uniform oscillation of the laser cannot be carried out. Furthermore, there is a problem in terms of the directionality of the emitted laser. As a result, the oscillated laser is degraded, thereby causing a reduction in the reliability of the semiconductor laser device.

Therefore, in the technical field, it has been required to provide a semiconductor laser device manufacturing method capable of preventing formation of grains when semiconductor laser devices of a wafer-level state are cleaved, thereby providing a semiconductor laser device exhibiting superior laser oscillation characteristics and superior reliability.

### SUMMARY OF THE INVENTION

The present invention has been made in view of the above mentioned problems, and an object of the invention is to provide a semiconductor laser device in which its ridge is arranged to be spaced, at opposite longitudinal ends thereof, apart from cleaved surfaces by a certain distance such that it is not exposed to the cleaved surfaces, thereby being capable of simplifying the structure of the cleaved surfaces to prevent grains from being formed at the cleaved surfaces, so that it exhibits superior laser oscillation characteristics and superior reliability, and to provide a method for manufacturing the semiconductor laser device.

In accordance with one aspect, the present invention provides a semiconductor laser device comprising: a first-conductivity type substrate; a first-conductivity type clad layer formed over the substrate; an active layer formed over the first-conductivity type clad layer; a second-conductivity type clad layer formed over the active layer while having a ridge spaced apart, at respective opposite longitudinal ends thereof, from a laser emitting end surface and an end surface opposite to the laser emitting end surface by a predetermined gap; and a current blocking layer formed on the second-conductivity type clad layer around the ridge.

Preferably, the predetermined gap is 5 μm or more while corresponding to 10% or less of a distance between the laser emitting end surface and the opposite end surface.

In accordance with another aspect, the present invention provides a method for manufacturing a semiconductor laser device, comprising the steps of: sequentially forming over at least a first-conductivity type clad layer, an active layer and a second-conductivity type clad layer over a substrate; forming, on the second-conductivity type clad layer, a mask adapted to form a ridge such that the ridge is spaced apart, at respective opposite longitudinal ends thereof, from a laser emitting end surface and an end surface opposite to the laser emitting end surface by a predetermined gap; etching the second-conductivity type clad layer to a predetermined depth by use of the mask, thereby forming the ridge; and forming a current blocking layer made of a first-conductivity type semiconductor material on the etched second-conductivity type clad layer around the ridge.

Preferably, the step of forming the ridge comprises the steps of forming a ridge structure in accordance with a dry etching process, and removing defects formed on a surface of the ridge structure in accordance with a wet etching process, thereby forming the ridge.

### BRIEF DESCRIPTION OF THE DRAWINGS

The above objects, and other features and advantages of the present invention will become more apparent after reading the following detailed description when taken in conjunction with the drawings, in which:

FIG. 1a is a perspective view illustrating a conventional semiconductor laser device;

FIG. 1b is a plan view illustrating the structure of the conventional semiconductor laser device in a state in which a ridge has been formed;

FIG. 2 is a plan view illustrating a wafer-level state of the conventional semiconductor laser device;

FIGS. 3a to 3c are cross-sectional views showing diverse grains formed at the cleaved surface of the conventional semiconductor laser device;

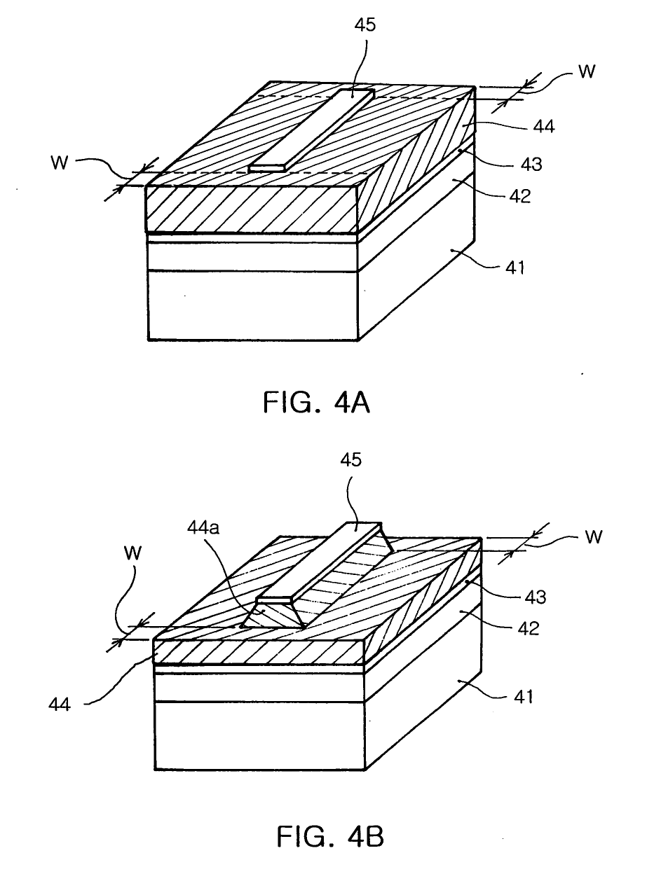

FIGS. 4a to 4c are perspective views illustrating sequential processing steps of a method for manufacturing a semiconductor laser device having a higher-order mode absorption layer in accordance with the present invention, respectively;

FIGS. 5a and 5b are cross-sectional views illustrating the structure of the semiconductor laser device according to the illustrated embodiment of the present invention, respectively; and

FIG. 6 is a plan view illustrating a wafer-level state of the semiconductor laser device according to the embodiment of the present invention.

### DESCRIPTION OF THE PREFERRED EMBODIMENTS

Now, preferred embodiments of the present invention will be described in detail with reference to the annexed drawings.

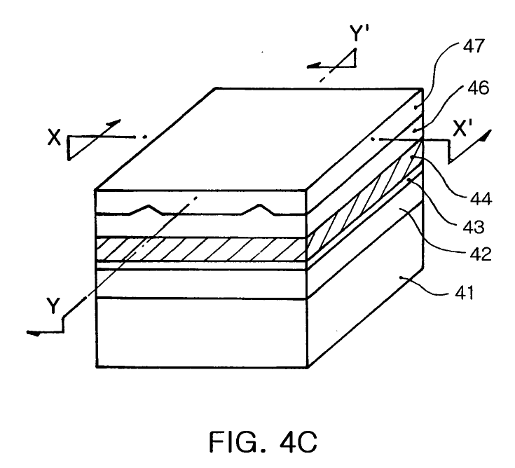

FIGS. 4a to 4c illustrate sequential processing steps of a method for manufacturing a semiconductor laser device having a higher-order mode absorption layer in accordance with the present invention, respectively. Although the embodiment illustrated in FIGS. 4a to 4c is associated with an AlGaAs-based semiconductor laser device adapted to oscillate a laser having a wavelength of 780 nm, the present invention is not limited thereto.

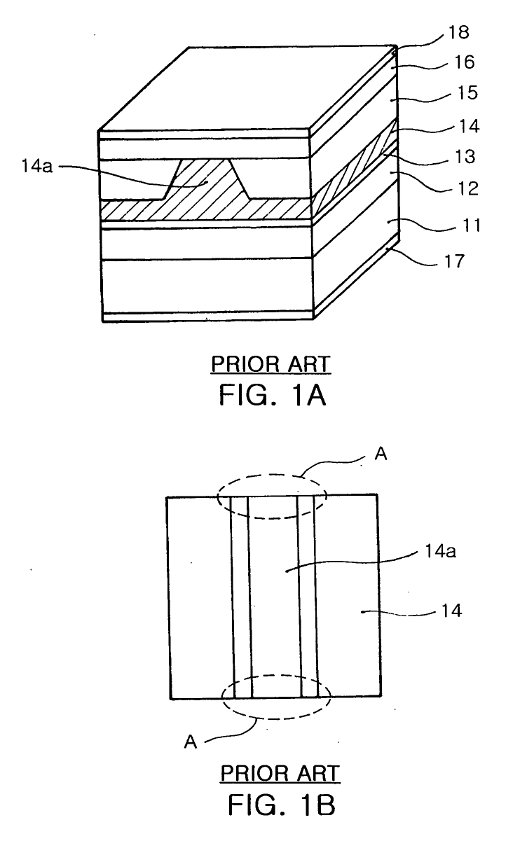

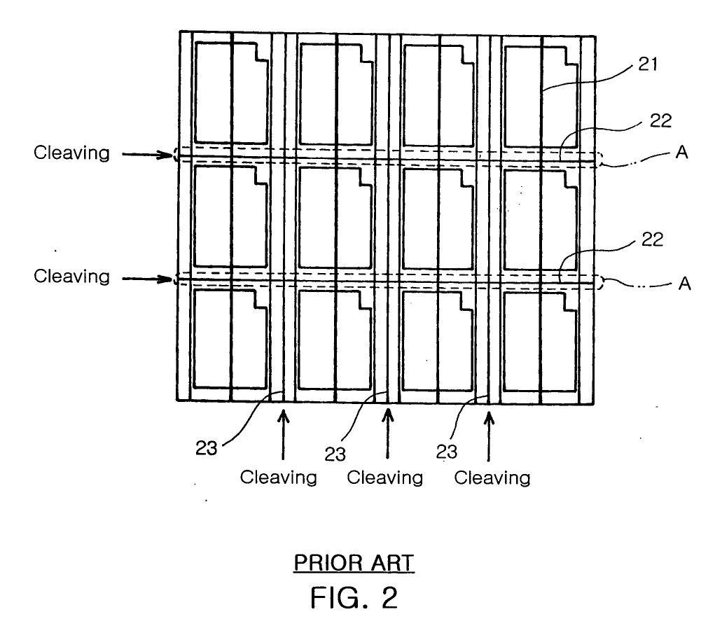

In order to manufacture the semiconductor laser device according to the illustrated embodiment of the present invention, a first-conductivity type semiconductor substrate 41 is first prepared, as shown in FIG. 1a. The first-conductivity type semiconductor substrate 41 is formed, at its lower surface, with a first electrode (not shown) made of a certain alloy. Thereafter, a first-conductivity type clad layer 42, an active layer 43, and a second-conductivity type clad layer 44 are sequentially formed over the first-conductivity type semiconductor substrate 41, using an MOCVD or MOVPE process. Where the semiconductor laser device is an AlGaAs-based semiconductor laser device, the substrate 41 may typically be an n type GaAs substrate. In this case, the first and second-conductivity type clad layers 42 and 44 may be n and p type AlGaAs-based clad layers, respectively, whereas the active layer 43 may be an AlGaAs-based active layer having a quantum well structure. The above described layers are formed in a sequential and continuous manner in the above described order. Hereinafter, this formation procedure will be referred to as a “primary growth procedure”. Although not shown in FIG. 4a, a first-conductivity type buffer layer may be interposed between the substrate 41 and the first-conductivity type clad layer 42. However, the first-conductivity type buffer layer is adapted only for a crystal alignment between the substrate 41 and the first-conductivity type clad layer 42. Accordingly, this first-conductivity type buffer layer will be described as being included in the first-conductivity type clad layer 42 in the following description and the claims.

After completion of the primary growth procedure, a mask 45 is formed on the second-conductivity type clad layer 44. The region where the mask 45 is arranged corresponds to a region where a ridge is to be formed. That is, as the mask region is not etched in a subsequent etching process, the ridge will be formed. For the mask 45, a dielectric film, for example, an oxide film such as an SiO₂ film or a nitride film such as an SiN film, may be used. An etch stop layer (not shown) may be included in the second-conductivity type clad layer 44 so as to prevent the second-conductivity type clad layer 44 from being excessively etched in an etching process.

In conventional methods for manufacturing a semiconductor laser device, a mask is formed such that it extends from the laser emitting end surface of the semiconductor laser device to an end surface opposite to the laser emitting end surface. In accordance with the present invention, however, the mask 45 is arranged such that it is spaced, at respective opposite longitudinal ends thereof, apart from both the laser emitting end surface of the semiconductor laser device and the opposite end surface by a predetermined gap W. Accordingly, when the second-conductivity type clad layer 44 is subsequently subjected to an etching process, only the portions thereof each corresponding to the predetermined gap W are etched. Thus, the ridge is spaced, at respective longitudinal ends thereof, apart from both the laser emitting end surface and the opposite end surface by a certain gap.

The predetermined gap W has to be 5 μm or more. Preferably, the predetermined gap W corresponds to 10% or less of the distance between the laser emitting end surface and the opposite end surface. For example, where the distance between the laser emitting end surface and the opposite end surface is 200 μm, the predetermined gap W should not be less than 5 μm, but not more than 20 μm. Where the gap W is less than 5 μm, the ridge may be exposed to a cleaved surface due to a cleaving error possibly occurring upon cleaving the wafer in a bar making process. For this reason, it is preferred that the gap W should not be less than 5 μm. Also, where the gap W exceeds 10% of the distance between the laser emitting end surface and the opposite end surface, a decrease in the gain of optical power occurs. As a result, the characteristics of the semiconductor laser device may be degraded. Therefore, it is preferred that the gap W correspond to 10% or less of the distance between the laser emitting end surface and the opposite end surface.

Thereafter, the second-conductivity type clad layer 44 is etched to a desired depth at regions other than the region where the mask 45 is arranged, as shown in FIG. 4b. Since the mask 45 is spaced, at respective longitudinal ends thereof, apart from both the laser emitting end surface and opposite end surface of the semiconductor laser device, as described above, the etched portions of the second-conductivity type clad layer 44 correspond to opposite mesa type lateral portions of the ridge 44a, the region defined between the laser emitting end surface of the semiconductor laser device and the facing end of the ridge 44a while corresponding to the gap W, and the region defined between the end surface of the semiconductor laser device opposite to the laser emitting end surface and the facing end of the ridge 44a while corresponding to the gap W, respectively. For the etching process for forming the ridge 44a, both dry and wet etching processes are used.

Generally, etching processes are classified into a dry etching process and a wet etching process. The dry etching process can provide high resolution and anisotropic characteristics of an etched surface essentially required in association with a planarization technique. For such a dry etching process, there are plasma etching reactive ion etching, and reactive ion beam etching processes. In most cases, these etching processes use inert ions and reactive gas to provide anisotropic characteristics of an etched surface. However, the dry etching process may involve damage of an etched thin film surface caused by exposure to reactive chemical gas, irradiation of ions, and radiation of plasma. For this reason, a reduction in etching speed and a degradation in electrical device performance. In other words, irradiation of ions with energy of a certain level may cause formation of a residual layer, penetration of impurities and etchant gas, and lattice structure defects. On the other hand, the wet etching process provides isotropic characteristics of an etched surface. Such a wet etching process is widely used in semiconductor processes by virtue of its low cost, high power, and superior selectivity. Also, the wet etching process does not cause any damage to the wafer because it is carried out at low temperature.

Although most conventional methods for manufacturing a semiconductor laser devices use the wet etching process, it is preferable to use both the dry and wet etching processes in forming a ridge in accordance with the present invention. In accordance with the present invention, the formation of the ridge is achieved by first forming a ridge structure through a dry etching process, and then removing damaged portions on the etched surface formed in the dry etching process, through a wet etching process. Where a ridge is formed, only using a dry etching process, there may be damaged portions on the etched surface, so that a degradation in device performance occurs. On the other hand, where a ridge is formed, only using a wet etching process, the stripe structure of the ridge has an inverted mesa structure at forward and backward surfaces thereof, even though it has a mesa structure at opposite later surfaces thereof. Such an inverted mesa structure causes a problem in that when a current blocking layer is subsequently formed, it may be ineffectively grown over the lower surface of the inverted mesa structure. To this end, in accordance with the present invention, the formation of the ridge is achieved by first forming a ridge structure through a dry etching process, and then removing damaged portions on the etched surface formed in the dry etching process, through a wet etching process. Although the ridge has been described as having a mesa structure in the illustrated embodiment, the present invention is not limited to this ridge structure. The present invention may be applied to diverse mesa structures.

After removal of the mask 45, a current blocking layer 46 is formed on the second-conductivity type clad layer 44 around the ridge 44a, as shown in FIG. 4c. A second-conductivity type ohmic contact layer 47 is formed over the current blocking layer 46. Since the ridge 44a has been formed in the previous process such that it is spaced, respective opposite longitudinal ends thereof, apart from both the laser emitting end surface and opposite end surface of the semiconductor laser device by a certain gap, it is not exposed to the laser emitting end surface and opposite end surface of the semiconductor laser device, as shown in FIG. 4c. Accordingly, the structure of the cleaved surface formed upon cleaving the semiconductor laser device from a wafer-level state is simplified, as compared to that of the laser emitting end surface (cleaved surface) in the conventional semiconductor laser device shown in FIG. 1. In particular, the ridge structure, to which a cleaving force is applied in a perpendicular direction, is not exposed to the cleaved surfaces, so that the application direction of the cleaving force does not vary. Accordingly, it is possible to reduce formation of grains at the cleaved surfaces (the laser emitting end surface and opposite end surface of the semiconductor laser device).

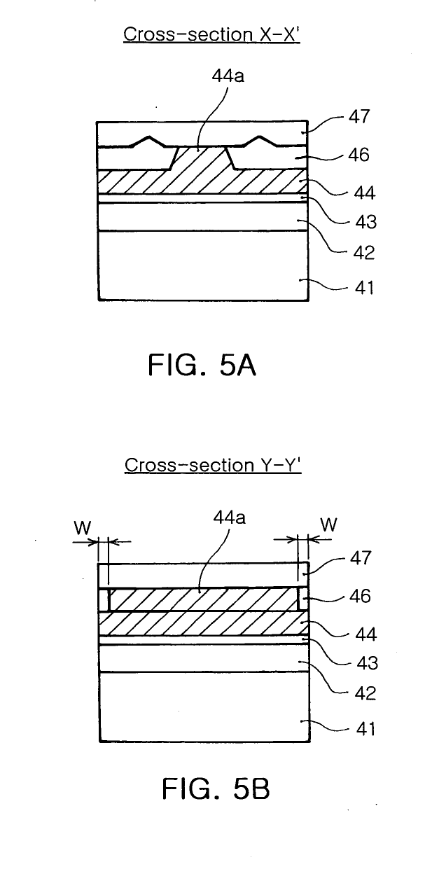

FIGS. 5a and 5b are cross-sectional views illustrating the structure of the semiconductor laser device according to the illustrated embodiment of the present invention, respectively. FIG. 5a is a cross-sectional view taken along the line X-X′ in FIG. 4c. As shown in FIG. 5a, the cross-section of the semiconductor laser device according to the present invention, which is taken along a central portion of the semiconductor laser device in parallel to the laser emitting end surface, has the same structure as that of the conventional semiconductor laser device. That is, the semiconductor laser device according to the present invention has a structure including: the first-conductivity type substrate 41; the first-conductivity type clad layer 42, active layer 43, and second-conductivity type clad layer 44 having the ridge 44a sequentially formed over the first-conductivity type substrate 41, in this order; the current blocking layer 46 formed on the second-conductivity type clad layer 44 around the ridge 44a, and the second-conductivity type ohmic contact layer 47 formed to cover the ridge 44a and current blocking layer 46.

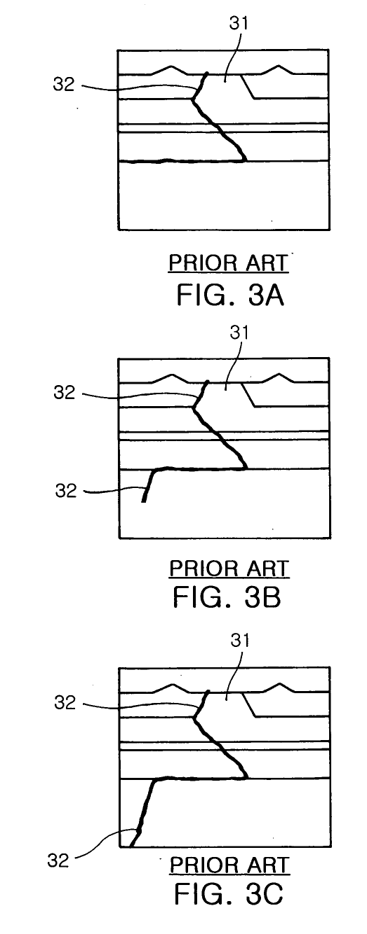

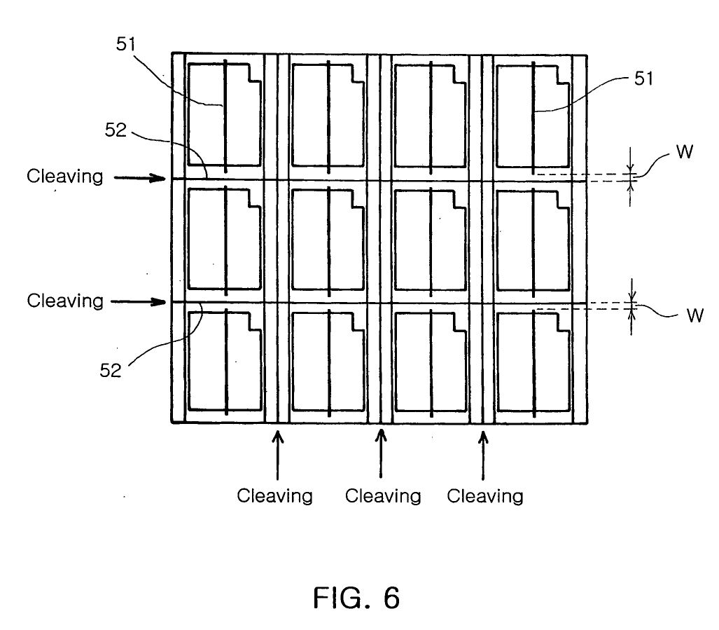

In particular, the semiconductor laser device manufacturing method according to the present invention can be easily implemented through an appropriate mask modification adapted to form a desired ridge structure, without any addition or modification of processes. FIG. 6 is a plan view illustrating the wafer-level state of the semiconductor laser device according to the illustrated embodiment of the present invention. In the wafer-level state of the conventional semiconductor laser devices shown in FIG. 2, the masks (or ridges) of semiconductor laser devices aligned in a longitudinal direction of the ridges are connected to one another, so that the ridges are cleaved in a cleaving process. However, in the wafer-level state of semiconductor laser devices of the present invention shown in FIG. 6, the masks (or ridges) of semiconductor laser devices aligned in a longitudinal direction of the ridges are spaced, respective longitudinal ends thereof, apart from the associated bar making lines 52 by the predetermined gap W, respectively. Accordingly, the ridges are not cleaved in a subsequent cleaving process for cleaving the wafer-level structure into chip-level structures, so that they are exposed to associated cleaved surfaces.

That is, in accordance with the present invention, such a structure can be easily implemented by modifying the mask forming process of the conventional method, in which masks respectively associated with semiconductor laser devices aligned in a longitudinal direction of ridges are formed to have a connected structure, into a method in which the masks are formed to have separate chip structures, respectively, such that each of them is spaced apart from an associated bar making line by the predetermined gap W.

Accordingly, the ridge formed on the second-conductivity type clad layer in each semiconductor laser device is spaced apart from both the laser emitting end surface and the opposite end surface, so that it is not exposed to the cleaved surfaces (the laser emitting end surface and the opposite end surface) of the semiconductor laser device. As a result, the laminated structure of the cleaved surfaces (the laser emitting end surface and the opposite end surface) in the semiconductor laser device is simplified, so that the application direction of the cleaving force does not vary. Accordingly, it is possible to prevent formation of grains at the cleaved surfaces. It is also possible to improve the laser oscillation of the semiconductor laser device while preventing a degradation in performance.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

As apparent from the above description, the present invention provides a semiconductor laser device in which its ridge is arranged to be spaced, at respective longitudinal ends thereof, apart from cleaved surfaces by a certain distance such that it is not exposed to the cleaved surfaces, thereby being capable of simplifying the structure of the cleaved surfaces to prevent grains from being formed at the cleaved surfaces, so that it exhibits superior laser oscillation characteristics and superior reliability.

What is claimed is:

1. A semiconductor laser device comprising:
a first-conductivity type substrate;
a first-conductivity type clad layer formed over the substrate;
an active layer formed over the first-conductivity type clad layer;
a second-conductivity type clad layer formed over the active layer while having a ridge spaced apart, at respective opposite longitudinal ends thereof, from a laser emitting end surface and an end surface opposite to the laser emitting end surface by a predetermined gap; and
a current blocking layer formed on the second-conductivity type clad layer around the ridge.

2. The semiconductor laser device according to claim 1, wherein the predetermined gap is 5 μm or more while corresponding to 10% or less of a distance between the laser emitting end surface and the opposite end surface.

3. A method for manufacturing a semiconductor laser device, comprising the steps of:
sequentially forming over at least a first-conductivity type clad layer, an active layer and a second-conductivity type clad layer over a substrate;
forming, on the second-conductivity type clad layer, a mask adapted to form a ridge such that the ridge is spaced apart, at respective opposite longitudinal ends thereof, from a laser emitting end surface and an end surface opposite to the laser emitting end surface by a predetermined gap;
etching the second-conductivity type clad layer to a predetermined depth by use of the mask, thereby forming the ridge; and
forming a current blocking layer made of a first-conductivity type semiconductor material on the etched second-conductivity type clad layer around the ridge.

4. The method according to claim 3, wherein the predetermined gap is 5 μm or more while corresponding to 10% or less of a distance between the laser emitting end surface and the opposite end surface.

5. The method according to claim 3, wherein the step of forming the ridge comprises the steps of:
forming a ridge structure in accordance with a dry etching process; and
removing defects formed on a surface of the ridge structure in accordance with a wet etching process, thereby forming the ridge.
